(19) United States
(12) Patent Application Publication
(10) Pub. No.: US 2025/0118644 A1
(43) Pub. Date: Apr. 10, 2025

(54) CIRCUIT BOARD AND ELECTRONIC DEVICE PACKAGE

(71) Applicant: SAMSUNG ELECTRO-MECHANICS CO., LTD., Suwon-si (KR)

(72) Inventors: Youngwoong Cho, Suwon-si (KR); Heun Young Seo, Suwon-si (KR)

(73) Assignee: SAMSUNG ELECTRO-MECHANICS CO., LTD., Suwon-si (KR)

(21) Appl. No.: 18/647,764

(22) Filed: Apr. 26, 2024

(30) Foreign Application Priority Data
Oct. 4, 2023 (KR) 10-2023-0131801

(51) Int. Cl. H01L 23/498; H01L 21/48; H01L 21/56; H01L 23/13; H01L 23/31

(52) U.S. Cl. CPC H01L 23/49822; H01L 21/4857; H01L 21/56; H01L 23/13; H01L 23/3128

(57) ABSTRACT

A circuit board according to the present disclosure includes: a substrate including a first insulating layer with a first surface, and a cavity penetrating the first insulating layer in a direction perpendicular to the first surface; a first wiring layer embedded in the first insulating layer and having at least one surface exposed from the first insulating layer; and a buffer portion disposed adjacent to an edge of the cavity in the first insulating layer and having a receiving surface retreated further from the exposed surface of the first wiring layer. An electronic device package according to the present disclosure includes: an electronic device accommodated in a cavity of the circuit board; an insulation material disposed on the buffer portion to fill and insulate between the electronic device and the first wiring layer; and a redistribution layer disposed on the first surface of the first insulating layer and to which the electronic device is connected.

### CROSS-REFERENCE TO RELATED APPLICATION

This application claims priority to and the benefit of Korean Patent Application No. 10-2023-0131801 filed in the Korean Intellectual Property Office on Oct. 4, 2023, the entire contents of which are incorporated herein by reference.

### TECHNICAL FIELD

The present disclosure relates to a circuit board and an electronic device package.

### BACKGROUND

Recently, semiconductor package technology is evolving in accordance with the trend of continued down-sizing and multi-functionalization of electronic products. Such evolution is mainly related to the emergence of new technology platforms such as a fan-out panel level package (FOPLP), a fan-out wafer level package (FOWLP), and a side by side packaging. The new packaging technology includes improvements in heat dissipation characteristics by increasing the thickness and size of the chip.

However, during FOPLP packaging, a distance between a chip mounting area and a copper (Cu) pattern inside the substrate is narrowed due to the expansion of a chip size within a printed circuit board (PCB). Thus, there is a risk that resin bleeding may occur on the copper side when applying resin after chip mounting during a panel level package (PLP) process. When electrical conduction between layers is interrupted due to resin bleeding, the performance and stability of the product may be affected. Therefore, there is a need for technology to ensure quality of a cavity area of the printed circuit board, which is the chip mounting area.

### SUMMARY OF THE INVENTION

One aspect of an embodiment is to provide a circuit board that can prevent a resin application defect during a panel level package (PLP) process by improving the design of a cavity area, and an electronic device package with an electronic device mounted on the circuit board.

However, the problems to be solved through embodiments of the present disclosure are not limited to the above-mentioned problems and may be expanded in various ways within the scope of technical ideas included in the present disclosure.

A circuit board according to an embodiment includes: a substrate including a first insulating layer with a first surface, and a cavity penetrating the first insulating layer in a direction perpendicular to the first surface; a first wiring layer embedded in the first insulating layer and having at least one surface exposed from the first insulating layer; and a buffer portion disposed adjacent to an edge of the cavity in the first insulating layer and having a receiving surface retreated further from the at least one surface of the first wiring layer exposed from the first insulating layer.

The first wiring layer may include a plurality of wiring patterns, the receiving surface of the buffer portion may be retreated further from the at least one surface of the first wiring layer exposed from the first insulating layer of an innermost wiring pattern closest to the cavity among the plurality of wiring patterns.

A first side surface of the innermost wiring pattern may be covered by the first insulating layer, and a second side surface of the innermost wiring pattern may include a portion exposed from the first insulating layer.

The innermost wiring pattern may include a portion of a side surface, exposed toward the cavity.

The at least one surface of the first wiring layer exposed from the first insulating layer may be retreated further from the first surface of the first insulating layer.

The receiving surface of the buffer portion may be configured to face a same direction as the first surface of the first insulating layer.

An electronic device package according to another embodiment includes: a substrate including a first insulating layer with a first surface, and a cavity penetrating the first insulating layer in a direction perpendicular to the first surface; a first wiring layer embedded in the first insulating layer and having at least one surface exposed from the first insulating layer; a buffer portion disposed adjacent to an edge of the cavity in the first insulating layer and having a receiving surface retreated further from the at least one surface of the first wiring layer exposed from the first insulating layer; an electronic device accommodated in the cavity; an insulation material disposed on the buffer portion to fill a gap between the electronic device and the first wiring layer and insulate the electronic device from the first wiring layer; and a redistribution layer disposed on the first surface of the first insulating layer and to which the electronic device is connected.

The electronic device package may further include an insulation protective layer disposed between the first surface of the first insulating layer and the redistribution layer to cover the first wiring layer.

The first wiring layer may include a plurality of wiring patterns, and the receiving surface of the buffer portion may be retreated further from a first surface of an the innermost wiring pattern closest to the cavity among the plurality of wiring patterns exposed from the first insulating layer.

A first side surface of the innermost wiring pattern may be covered by the first insulating layer, and a second side surface of the innermost wiring pattern may include a portion exposed from the first insulating layer.

The insulation material may be disposed in contact with the first side surface of the innermost wiring pattern on the buffer portion.

The insulation material may include a first surface disposed on the receiving surface of the buffer portion to be retreated further from the first surface of the innermost wiring pattern exposed from the first insulating layer.

The exposed first surface of the first wiring layer may be retreated further from the first surface of the first insulating layer.

The receiving surface of the buffer portion may be configured to face a direction that is the same as the first surface of the first insulating layer.

The insulation material may include a silicon oxide (SiO₂) filler.

The insulation material may include an Ajinomoto build-up film (ABF).

According to the circuit board and the electronic device package of the embodiments, the resin bleeding that causes the resin to flow into the copper pattern area of the circuit board when applying resin after chip mounting during a panel level package (PLP) process can be prevented from occurring by improving the design of the cavity area on which the chip is mounted.

Contact defects between layers within the package can be improved and the packaging yield can be secured by preventing resin bleeding around the chip mounting area.

### BRIEF DESCRIPTION OF THE DRAWINGS

FIG. 1 is a cross-sectional view of a circuit board according to an embodiment.

FIG. 2 is a cross-sectional view of an electronic device package in which an electronic device is mounted on the circuit board of FIG. 1.

FIG. 3 to FIG. 15 are process cross-sectional views of a method for manufacturing a circuit board and an electronic device package by mounting an electronic device.

### DETAILED DESCRIPTION OF THE EMBODIMENTS

Hereinafter, with reference to the accompanying drawing, an embodiment will be described in detail and thus that a person of an ordinary skill can easily practice it in the technical field to which the present invention belongs. The drawings and description are to be regarded as illustrative in nature and not restrictive. Like reference numerals designate like elements throughout the specification. In addition, some constituent elements in the accompanying drawings are exaggerated, omitted, or schematically illustrated, and the size of each constituent element does not fully reflect the actual size.

The accompanying drawing is only for easy understanding of the embodiments disclosed in this specification, and the technical idea disclosed in this specification is not limited by the accompanying drawing, and it should be understood that all changes, equivalents, or substitutes included in the spirit and scope of the present invention are included.

Terms including ordinal numbers such as first, second, and the like may be used to describe elements of various configurations, but the constituent elements are not limited by the terms. The terms are only used to distinguish one constituent element from another.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

Throughout the specification, terms such as “include” or “have” are intended to designate the presence of features, numbers, steps, actions, constituent elements, parts, or combinations of these described in the specification, but it is to be understood that the possibility of the presence or addition of one or more other features, elements, numbers, steps, actions, constituent elements, parts, or combinations thereof is not preliminarily excluded. Therefore, when a part “comprises” a certain constituent element, this means that other constituent elements may be further included, rather than excluding other constituent elements, unless otherwise stated.

In addition, in the entire specification, when it is referred to as “on a plane”, it means when an object is viewed from above, and when it is referred to as “on a cross-section”, it is viewed from the side when the object is cut vertically.

In addition, the expression “connected to” in the entire specification not only means that two or more constituent elements are directly connected to, but also means that two or more constituent elements are indirectly connected through other constituent elements, physically connected to, or electrically connected, or being referred to by different names depending on the position or function, but is integral.

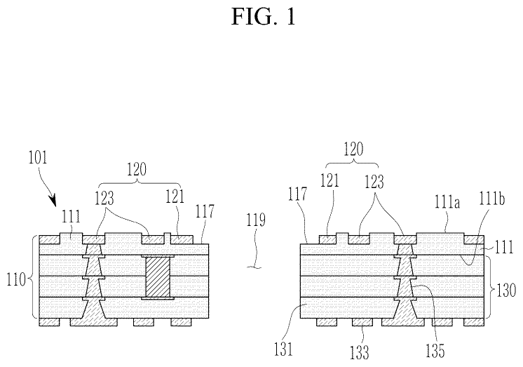

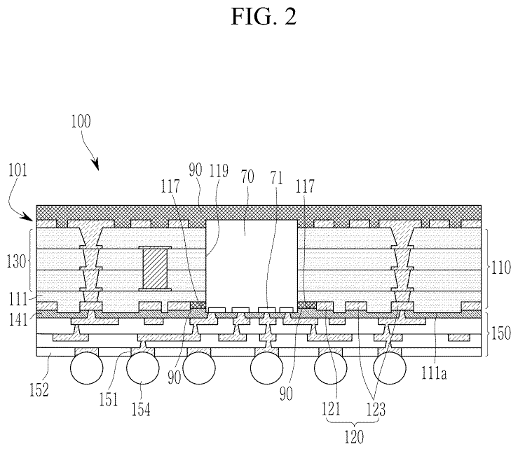

FIG. 1 is a cross-sectional view of a circuit board according to an embodiment, and FIG. 2 is a cross-sectional view of an electronic device package in which an electronic device is mounted on the circuit board of FIG. 1.

Referring to FIG. 1, a circuit board 101 according to the present embodiment includes a substrate 110 including a first insulating layer 111 and a cavity 119 formed penetrating the first insulating layer 111, and a first wiring layer 120 embedded in the first insulating layer 111. The first insulating layer 111 and the first wiring layer 120 may be formed of an embedded trace substrate (ETS) structure. The circuit board 101 may be used as a printed circuit board (PCB) for a semiconductor package.

The first insulating layer 111 may include a first surface 111a and a second surface 111b that face each other. The first insulating layer 111 may include a resin insulating layer. For the first insulating layer 111, a thermosetting resin such as epoxy resin, a thermoplastic resin such as polyimide, or a resin impregnated with a reinforcing member such as glass fiber or inorganic filler, for example, prepreg may be used. In addition, the first insulating layer 111 may include, but is not limited to, thermosetting resin and/or photo-curing resin.

At least one surface of the first wiring layer 120 may be exposed from the first insulating layer 111. The first wiring layer 120 may have an upper surface that is lower than an upper surface of the first insulating layer 111, and the upper surface of the first wiring layer 120 may be exposed. That is, the exposed surface of the first wiring layer 120 may be retreated further from the first surface 111a of the first insulating layer 111. The first wiring layer 120 may include copper (Cu), and the first wiring layer 120 may be exposed from the first insulating layer 111 and connected to terminals of external circuit components.

The cavity 119 may be formed by penetrating the substrate 110 in a direction perpendicular to the first surface 111a. An electronic device 70 (refer to FIG. 2) may be accommodated in the cavity 119. The electronic device 70 includes various devices such as active elements, passive elements, and integrated circuit (IC) chips, and may, for example, be a semiconductor chip.

The buffer portion 117 may be placed adjacent to an edge of the cavity 119 in the first insulating layer 111. The buffer portion 117 has a shape in which a portion of an upper end of the first insulating layer 111 is removed and may have a receiving surface that is retreated further from the exposed surface of the first wiring layer 120. That is, with respect to a height measured in the direction perpendicular to the first surface 111a of the first insulating layer 111, the receiving surface of the buffer portion 117 may be formed lower than the exposed surface of the first wiring layer 120. The receiving surface of the buffer portion 117 may be configured to face the same direction as the first surface 111a of the first insulating layer 111. The buffer portion 117 may be formed continuously or intermittently along the edge of the cavity 119.

The first wiring layer 120 may include a plurality of wiring patterns 121 and 123, the innermost wiring pattern 121, which is closest to cavity 119, among the plurality of wiring patterns 121 and 123 may be adjacent to the buffer portion 117. In this case, the receiving surface of the buffer portion 117 may be disposed lower than the exposed surface from the first insulating layer 111 of the innermost wiring pattern 121. Accordingly, one side surface of the innermost wiring pattern 121 may be covered by the first insulating layer 111, and the other side surface may be at least partially exposed from the first insulating layer 111. The exposed side surface of the innermost wiring pattern 121 may face toward the cavity 119. A first surface of the first insulating layer 111, covering one side surface of the innermost wiring pattern 121 may be higher than the exposed surface of the innermost wiring pattern 121. That is, the exposed surface of the innermost wiring pattern 121 may be disposed further retreated from the first surface of the first insulating layer 111.

The substrate 110 may include a build-up structure 130 that is disposed on the second surface 111b of the first insulating layer 111. The build-up structure 130 may include a build-up insulating layer, a build-up wiring layer, and a via layer 135. The build-up insulating layer may include a plurality of insulating layers, and the build-up wiring layer may include a plurality of wiring layers respectively embedded in the plurality of insulating layers, and electrical connection between layers may be established through a plurality of via layers 135. The cavity 119 may be formed by penetrating the build-up insulating layer. An outermost wiring layer 133 may be placed on the outermost insulating layer 131 of the build-up structure 130 disposed on the second surface 111b of the first insulating layer 111.

Referring to FIG. 2, an electronic device package 100 according to the present embodiment includes the circuit board 101 and an electronic device 70 received in the cavity 119 of the substrate 110 which is disposed on the circuit board 101. The electronic device 70 may be an integrated circuit (IC) chip or a semiconductor chip.

An insulation material 90 may be disposed around the electronic device 70 to secure the electronic device 70 accommodated in the cavity 119 and prevent unnecessary current flow with the wires of the circuit board 101. The insulation material 90 may be disposed within the cavity 119 by filling a space between the electronic device 70 and the first wiring layer 120 of the circuit board 101. In addition, the insulation material 90 may be arranged to cover the outermost wiring layer 133 on the outermost insulating layer 131, and may be arranged to fill a space between the outermost wiring layer 133 and the electronic device 70.

The buffer portion 117 disposed adjacent to the edge of the cavity 119 in the first insulating layer 111 of the circuit board 101 may have a lower receiving surface than the surface exposed from the first insulating layer 111 of the first wiring layer 120. More specifically, among the plurality of wiring patterns 121 and 123 that form the first wiring layer 120, the innermost wiring pattern 121, which is closest to the cavity 119, is adjacent to the buffer portion 117, and the receiving surface of the buffer portion 117 may be disposed lower than the exposed surface the innermost wiring pattern 121.

Accordingly, the insulation material 90 may be disposed on the receiving surface of the buffer portion 117 between the electronic device 70 and the innermost wiring pattern 121. In addition, the insulation material 90 may be disposed to be in contact with one side surface of the innermost wiring pattern 121 on the receiving surface of the buffer portion 117, and may have one surface retreated further from the one surface exposed from the first insulating layer 111 of the innermost wiring pattern 121.

The insulation material 90 may include components different from the first insulating layer 111 and may be formed of a polymer insulation material with fluidity and adherence. The insulation material 90 may include a silicon oxide (SiO₂) filler that improves adherence and insulation, and may be an Ajinomoto build-up film (ABF).

The electronic device package 100 may be a fan-out semiconductor package, and may be arranged in the cavity 119 of the circuit board 101 such that a connection terminal 71 of the electronic device 70 may be disposed on the first surface 111a of the first insulating layer 111 that forms the substrate 110. One surface of a redistribution layer 150 is disposed on the first surface 111a and thus the electronic device 70 may be connected thereto, and the first wiring layer 120 of the circuit board 101 may be connected to the redistribution layer 150. A connection pad 151 is disposed on the other surface of the redistribution layer 150, and the connection pad 151 may be partially exposed while being covered with a solder resist layer 152. A connection terminal 154 may be connected to the exposed portion of the connection pad 151.

At least a part of the electronic device 70 and the outermost insulating layer 131 of the substrate 110 may be covered by the insulation material 90. The insulation material 90 may cover the outermost wiring layer 133 disposed on the outermost insulating layer 131 of the substrate 110. The outermost wiring layer 133 disposed on the outermost insulating layer 131 may be partially exposed from the insulation material 90 and thus may serve as a connection pad.

An insulation protective layer 141 may be disposed between the first surface 111a of the first insulating layer 111 and the redistribution layer 150. The insulation protective layer 141 may be an underfill resin that can be filled to protect the connection between the electronic device 70 and the redistribution layer 150. The insulation protective layer 141 may be formed by placing a photo imageable dielectric (PID) resin between the substrate 110 and the redistribution layer 150.

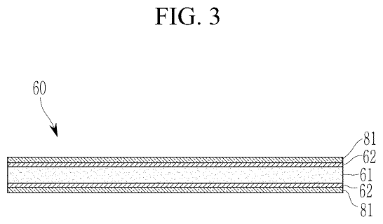

FIG. 3 to FIG. 15 are process cross-sectional views of a method for manufacturing a circuit board and an electronic device package by mounting an electronic device.

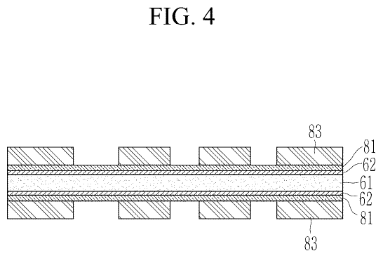

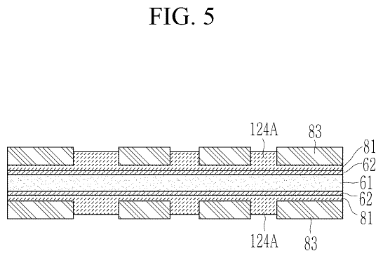

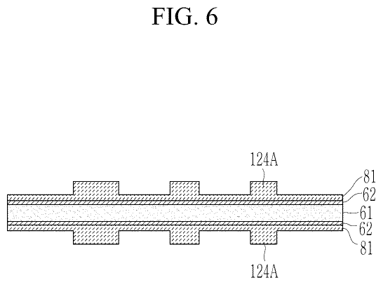

Referring to FIG. 3 to FIG. 6, a carrier substrate 60 where a first seed layer 81 is disposed on at least one side is prepared, and a first wiring pattern layer 124A is formed in the first seed layer 81 through a circuit forming process. The carrier substrate 60 may be a substrate in which a copper foil layer 62 is laminated on both sides of the insulation substrate 61, and the first seed layer 81 and the copper foil layer 62 may be separated from each other (refer to FIG. 3). A plating resist pattern 83 removed through exposing and developing only in an area where the first wiring pattern layer 124A is to be formed may be formed on the carrier substrate 60 (refer to FIG. 4). The first wiring pattern layer 124A may be formed by plating a conductive metal on a portion of the first seed layer 81 exposed through an opening of the patterned plating resist pattern 83 (refer to FIG. 5). The plating resist pattern is removed after the first wiring pattern layer 124A is formed (refer to FIG. 6).

The first seed layer 81 may be applied without limitation as long as it is used as a conductive metal for circuits in the circuit board field, and copper (Cu) is commonly used. The first wiring pattern layer 124A may be connected to the first seed layer 81 of the carrier substrate 60 and may contain the same type of metal as the first seed layer 81. For example, the first seed layer 81 and the first wiring pattern layer 124A may include copper (Cu).

In the present embodiment, it is shown that the first wiring pattern layer 124A is formed on both sides of the carrier substrate 60, but it is also possible to form the first wiring pattern layer 124A on only one side of the carrier substrate 60, and this is also included in the scope of the present disclosure.

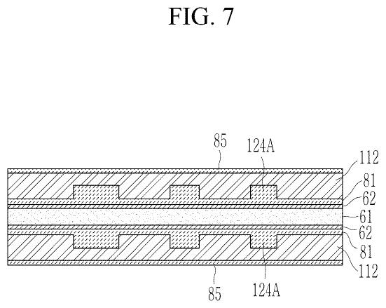

Referring to FIG. 7, an insulating layer 112 is stacked such that the first wiring pattern layer 124A is embedded, and a second seed layer 85 is formed on an upper surface of the insulating layer 112. The second seed layer 85 may be formed to form the second wiring pattern layer 134, and can be used without restrictions as long as it is a conductive metal, but copper is commonly used.

The insulating layer 112 may include a resin insulating layer. For the insulating layer 112, a thermosetting resin such as epoxy resin, a thermoplastic resin such as polyimide, or a resin impregnated with a reinforcing member such as glass fiber or inorganic filler, for example, prepreg may be used, and the insulating layer 112 may include, but is not limited to, thermosetting resin and/or photo-curing resin.

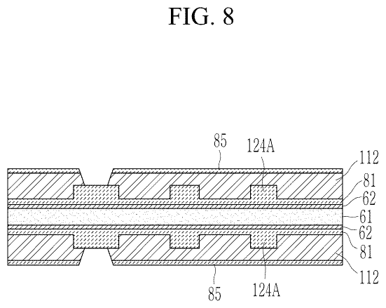

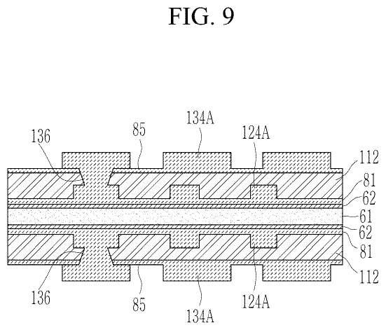

Referring to FIG. 8 and FIG. 9, a second wiring pattern layer 134A may be formed on the insulating layer 112 through a circuit forming process. The second wiring pattern layer 134A may be formed by a method similar to the method of forming the first wiring pattern layer 124A, and the second wiring pattern layer 134A may include the same type of material as the first wiring pattern layer 124A. In this case, in order to form a via 136 that connects the first wiring pattern layer 124A and the second wiring pattern layer 134A to each other, the insulating layer 112 is partially etched to expose a part of the first wiring pattern layer 124A (refer to FIG. 8), and the plating process may be performed on the exposed portion of the first wiring pattern layer 124A (refer to FIG. 9). Accordingly, a substrate with the embedded pattern portion is completed on both sides of the carrier substrate 60.

According to the illustrated embodiment, each substrate portion with embedded pattern includes one insulating layer 112, and two metal layers, that is, a first wiring pattern layer 124A and a second wiring pattern layer 134A, but is not limited thereto, and may include a larger number of build-up insulating layers and a larger number of build-up wiring pattern layers, which are also within the scope of the present disclosure.

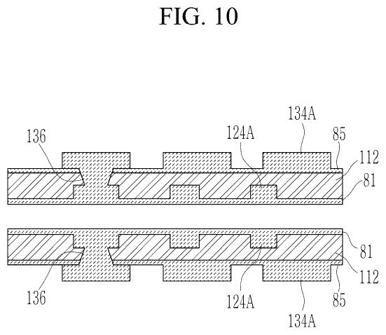

Referring to FIG. 10, an embedded pattern substrate is prepared by separating the first seed layer 81 and the carrier substrate 60. A pair of embedded pattern substrates can be obtained by separating the first seed layer 81 formed on both sides of the carrier substrate 60 from the copper foil layer 62, and a process may be applied individually to each pair of embedded pattern substrates.

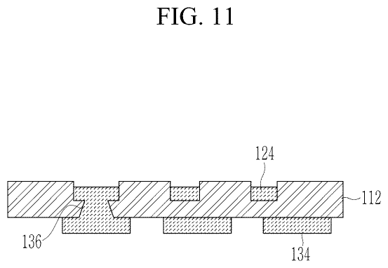

Referring to FIG. 11, the embedded pattern substrate obtained through the process described with reference to FIG. 10 is soft-etched to remove first seed layer 81 and the second seed layer 85. After removing the first seed layer 81 and the second seed layer 85, the first wiring pattern layer 124A embedded in the insulating layer 112 forms a first wiring layer 124 include a plurality of wiring patterns and the second wiring pattern layer 134A disposed on one surface of the insulating layer 112 forms the outermost wiring layer 134. In the process of removing the first seed layer 81, a surface of the first wiring pattern layer 124A exposed from the insulating layer 112 is also partially etched, and thus the first wiring layer 120 may be formed by being recessed more than the surface of the insulating layer 112.

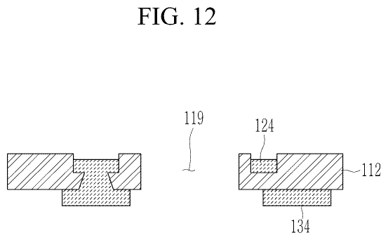

Referring to FIG. 12, a center of the embedded pattern substrate of FIG. 11 is etched, thereby forming a cavity 119. As a cavity processing, a variety of known processes may be used, and, for example, laser drilling, mechanical drilling, router process, and etching may be utilized.

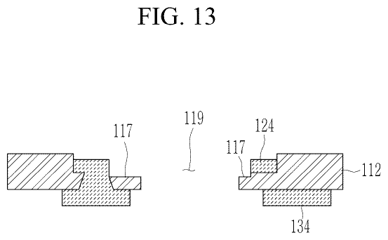

Referring to FIG. 13, the insulating layer 112 is partially etched along an edge of the cavity 110 of the circuit board of FIG. 12 to process a buffer portion 117. The buffer portion 117 may be processed to have a lower upper surface than the upper surface of the innermost wiring pattern closest to the cavity 119 among the first wiring layer 124. In addition, the buffer portion 117 may be processed such that one side surface of the innermost wiring pattern of the first wiring layer 124 is exposed toward the cavity 119. Processing of such a buffer portion 117 may be performed using a CO₂ laser.

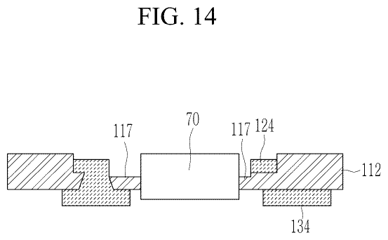

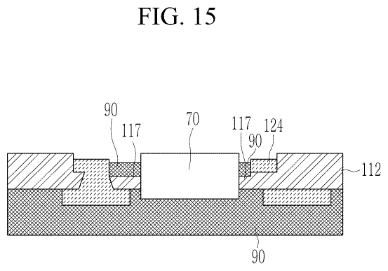

Referring to FIG. 14 and FIG. 15, the electronic device 70 may be accommodated in the cavity 110 of the circuit board and may be fixed by placing an insulation material 90 around the electronic device 70. The insulation material 90 may be disposed by filling between the electronic device 70 and the first wiring layer 124 of the circuit board in the cavity 119. In addition, the insulation material 90 may be disposed to cover the outermost wiring layer 134 on the insulating layer 112, and may be disposed by filling a space between the outermost wiring layer 134 and the electronic device 70. The insulation material 90 may fix the electronic device 70 accommodated in the cavity 119 to the circuit board and prevent unnecessary current flow with the wires of the circuit board.

The insulation material 90 may be disposed on the buffer portion 117 between the electronic device 70 and the innermost wiring pattern of the first wiring layer 124. In addition, the insulation material 90 may be arranged to contact one side surface of the innermost wiring pattern on the buffer portion 117 and may be formed lower than the upper surface of the innermost wiring pattern.

The insulation material 90 includes a component different from that of the first insulating layer 112, and may be formed of a polymer insulation material having fluidity and adherence. The insulation material 90 may include a silicon oxide (SiO₂) filler that increases adherence and insulation, and may be an Ajinomoto build-up film (ABF).

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A circuit board comprising:
a substrate including a first insulating layer with a first surface, and a cavity penetrating the first insulating layer in a direction perpendicular to the first surface;
a first wiring layer embedded in the first insulating layer and having at least one surface exposed from the first insulating layer; and
a buffer portion disposed adjacent to an edge of the cavity in the first insulating layer and having a receiving surface retreated further from the at least one surface of the first wiring layer exposed from the first insulating layer.

2. The circuit board of claim 1, wherein:
the first wiring layer comprises a plurality of wiring patterns, and
the receiving surface of the buffer portion is retreated further from the at least one surface of the first wiring layer exposed from the first insulating layer of an innermost wiring pattern closest to the cavity among the plurality of wiring patterns.

3. The circuit board of claim 2, wherein:
a first side surface of the innermost wiring pattern is covered by the first insulating layer, and a second side surface of the innermost wiring pattern includes a portion exposed from the first insulating layer.

4. The circuit board of claim 2, wherein:
the innermost wiring pattern comprises a portion of a side surface, exposed toward the cavity.

5. The circuit board of claim 1, wherein:
the at least one surface of the first wiring layer exposed from the first insulating layer is retreated further from the first surface of the first insulating layer.

6. The circuit board of claim 1, wherein:
the receiving surface of the buffer portion is configured to face a same direction as the first surface of the first insulating layer.

7. An electronic device package comprising:
a substrate including a first insulating layer with a first surface, and a cavity penetrating the first insulating layer in a direction perpendicular to the first surface;
a first wiring layer embedded in the first insulating layer and having at least one surface exposed from the first insulating layer;
a buffer portion disposed adjacent to an edge of the cavity in the first insulating layer and having a receiving surface retreated further from the at least one surface of the first wiring layer exposed from the first insulating layer;
an electronic device accommodated in the cavity;
an insulation material disposed on the buffer portion to fill a gap between the electronic device and the first wiring layer and insulate the electronic device from the first wiring layer; and
a redistribution layer disposed on the first surface of the first insulating layer and to which the electronic device is connected.

8. The electronic device package of claim 7, further comprising an insulation protective layer disposed between the first surface of the first insulating layer and the redistribution layer to cover the first wiring layer.

9. The electronic device package of claim 7, wherein:
the first wiring layer comprises a plurality of wiring patterns, and
the receiving surface of the buffer portion is retreated further from a first surface of an innermost wiring pattern closest to the cavity among the plurality of wiring patterns exposed from the first insulating layer.

10. The electronic device package of claim 9, wherein:
a first side surface of the innermost wiring pattern is covered by the first insulating layer, and a second side surface of the innermost wiring pattern includes a portion exposed from the first insulating layer.

11. The electronic device package of claim 10, wherein:
the insulation material is disposed in contact with the first side surface of the innermost wiring pattern on the buffer portion.

12. The electronic device package of claim 9, wherein:
the insulation material comprises a first surface disposed on the receiving surface of the buffer portion to be retreated further from the first surface of the innermost wiring pattern exposed from the first insulating layer.

13. The electronic device package of claim 7, wherein:
the exposed first surface of the first wiring layer is retreated further from the first surface of the first insulating layer.

14. The electronic device package of claim 7, wherein:
the receiving surface of the buffer portion is configured to face a direction that is same as the first surface of the first insulating layer.

15. The electronic device package of claim 7, wherein:
the insulation material comprises a silicon oxide (SiO₂) filler.

16. The electronic device package of claim 7, wherein:
the insulation material comprises an Ajinomoto build-up film (ABF).
